(19) United States
(12) Patent Application Publication
(10) Pub. No.: US 2006/0226848 A1
(43) Pub. Date: Oct. 12, 2006

(54) Mass-production LED test device for mass production

(75) Inventors: Tsan-Hsiung Lai, Hsin Chu City (TW); Kuei-Pao Chen, Hsin Chu City (TW)

Correspondence Address: TROXELL LAW OFFICE PLLC, SUITE 1404, 5205 LEESBURG PIKE, FALLS CHURCH, VA, 22041, US

(73) Assignee: Youngtek Electronics Corporation

(21) Appl. No.: 11/092,878

(22) Filed: Mar. 30, 2005

(51) Int. Cl. G01R 31/00

(52) U.S. Cl. 324/501

(57) ABSTRACT

A mass-production LED test device includes a control module, at least one integrating sphere module electrically connected to the control module and at least one test board corresponding to at the least one integrating sphere module. The integrating sphere module has an electrical output entrance, an optical output entrance and an optical input entrance. The test board has a plurality of pads to which a plurality of LEDs are electrically connected, respectively, for supplying required current of each LED. The optical input entrance of the integrating sphere module defines a predetermined measure for containing a predetermine amount of the LEDs at one time. The integrating sphere module has a plurality of probes corresponding to the predetermine amount of the LEDs, thereby to test the electrical character of each LED by a manner of one by one.

### BACKGROUND OF THE INVENTION

1. Field of the Invention

The present invention relates to an LED test device, and more particularly, to a mass-production LED test device being capable of testing a plurality of LEDs and increasing the production efficient.

2. Description of Related Art

Since an LED is applied with commercial goods from 1960s, due to its characteristics with high shake endurance, long service life, small power consumption, little giving-out heat, and so that the LED can be applied broadly for daily use, such as household appliances, indicative illumination for equipments or light sources. In recent years, enlarged outdoor display and the traffic lights are provided with the LEDs because of the colorful and highly illuminated requirement.

The principle of the LED is that a junction interface is formed between a P type semiconductor and a N type semiconductor, a Fermi levels of the P and N type semiconductors are aligned with each other and an electric field exists at the junction interface when no additional voltages are provided. If a suitable forward biased voltage is applied, electrons and holes are respectively injected into the P and N type semiconductors, and the electrons and the holes meet each other at the P/N junction interface in order to luminesce when the electrons drops back to a low energy state from a high energy state to release energy by means of light manner. By continuously both injecting electrons into the N type semiconductor and injecting holes into the P type semiconductor, the electrons and the holes repeat combining with each other to light, so that the LED is capable of illuminate. Corresponding to various designs and materials of the LED, the optical characteristics thereof vary.

After the LEDs are manufactured, electrical and optical characteristics thereof should be checked. The electrical characteristics include a forward bias voltage (VF), a reverse collapse voltage (VZ), a reverse current (IR), a data forward voltage (DVF), and the optical characteristics include a luminous intensity, a peak length, a wave wide, a chromaticity coordinates (CIE), a dominated length, a purity, a color temperature and so on. Therefore, the LEDs can be divided into various specifications according to these characteristics and then to be packaged and shipped. If there is any delay occurred, that will defer the deadline and break the company guarantee. In conventional steps for classifying the LEDs, the electrical characteristics of each LED is probed one by one and then the optical characteristics thereof are checked in turn, and that classifying flow can not meet the mass-production requirement and will reduce the manufacture efficiency and increase the costs while the LEDs are mass produced.

Referring to FIG. 1, a conventional LED test device includes a control unit 10a composed of computer and peripherals, an optical measurement device 20a electrically connected to the control unit 10a optical measurement device 20a, and a plurality of LEDs 30a disposed right under the the optical measurement device 20a. The optical measurement device 20a has an optical input entrance 21a that must be accurately aligned with the single LED 30a, otherwise light from the LED 30a is easy to disperse away to affect the accuracy of the optical measurement device 20a. In a addition, the optical measurement device 20a has an optical output entrance 22a and an electrical output entrance 23a connected to the control unit 10a individually. No matter the LED 30a or the optical measurement device 20a is moved to correspond to each other, a precise alignment therebetween should be obtained. After that, a current source is applied in order to illuminate, and optical characteristics are checked via the optical measurement device 20a. Furthermore, after or before mentioned step, the LEDs 30a or the optical measurement device 20a can be moved to touch each other to check the electrical characteristics. Finally, the LEDs 30a can be classified by the results of optical and electrical characteristics. These steps and the testing items are so complicated. A testing step for numerous LEDs 30a tested with these testing items obviously wastes time and labor to be a choke point during an LED manufacturing process.

Accordingly, as discussed above, the prior art still has some drawbacks that could be improved upon. The present invention aims to resolve the drawbacks in the prior art.

### SUMMARY OF THE INVENTION

A mass-production LED test device is provided to test a plurality of LEDs at one time, in order to increase manufacture efficiency for mass production.

The mass-production LED test device is provided with an integrating sphere module that defines a predetermine measure for containing a predetermine amount of the LEDs for testing the optical characteristics of the predetermine amount of the LEDs at the same time.

The mass-production LED test device is provided with a plurality of probes that corresponds with the predetermined of the LEDs for electrically testing.

The mass-production LED test device is provided a test board that can be designed according to the real requirement to load the LEDs to implement the electrical and optical tests.

The mass-production LED test device includes a control module, at least one integrating sphere module electrically connected to the control module and at least one test board corresponding to at the least one integrating sphere module. The integrating sphere module has an electrical output entrance, an optical output entrance and an optical input entrance. The test board has a plurality of pads to which a plurality of LEDs are electrically connected, respectively, for supplying required current of each LED. The optical input entrance of the integrating sphere module defines a predetermined measure for containing a predetermine amount of the LEDs at one time. The integrating sphere module has a plurality of probes corresponding to the predetermine amount of the LEDs, thereby to test the electrical character of each LED by a manner of one by one.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a schematic view of a conventional LED test device;

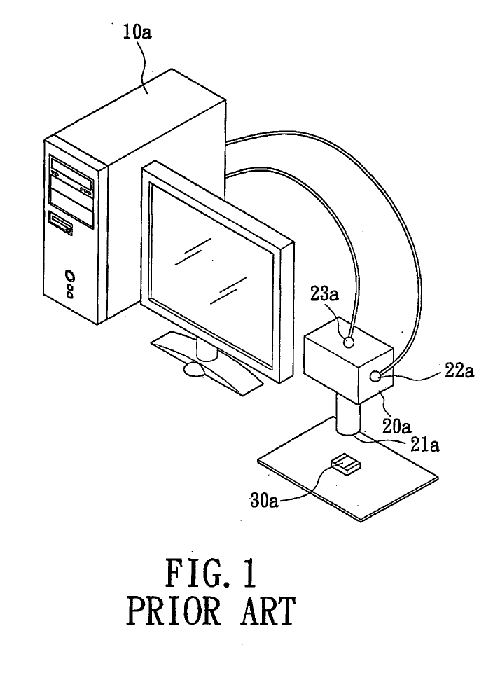

FIG. 2 is a schematic view of a mass-production LED test device according to the present invention; and

FIG. 3 is a schematic view of a plurality of integrating spheres and test boards corresponding to each other of the mass-production LED test device according to the present invention.

### DETAILED DESCRIPTION OF PREFERRED EMBODIMENTS

An integrating sphere is a hollow sphere, and can be defined with amount of input and output holes, an inner wall of the integrating sphere is covered with a layer of diffusion coating. When light goes into the integrating sphere, the inner wall thereof collects light reflected in all directions, and then transmit the light outwardly via the input and output holes after the layer of diffusion coating absorbs some energy. The collected light can be further implemented qualitative or quantitative analysis, such as light power, waveform or energy thereof, and can be transformed to get corresponding parameters of the original incident light.

An integrating sphere module of a mass-production LED test device according to the present invention is provided to collect light without precise alignment over a specific LED.

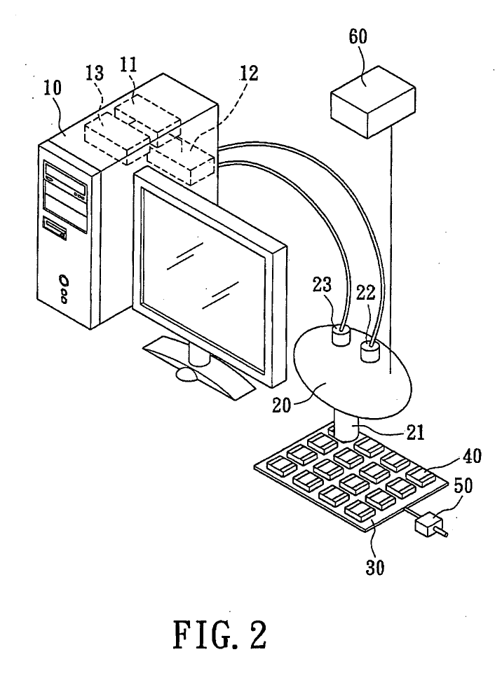

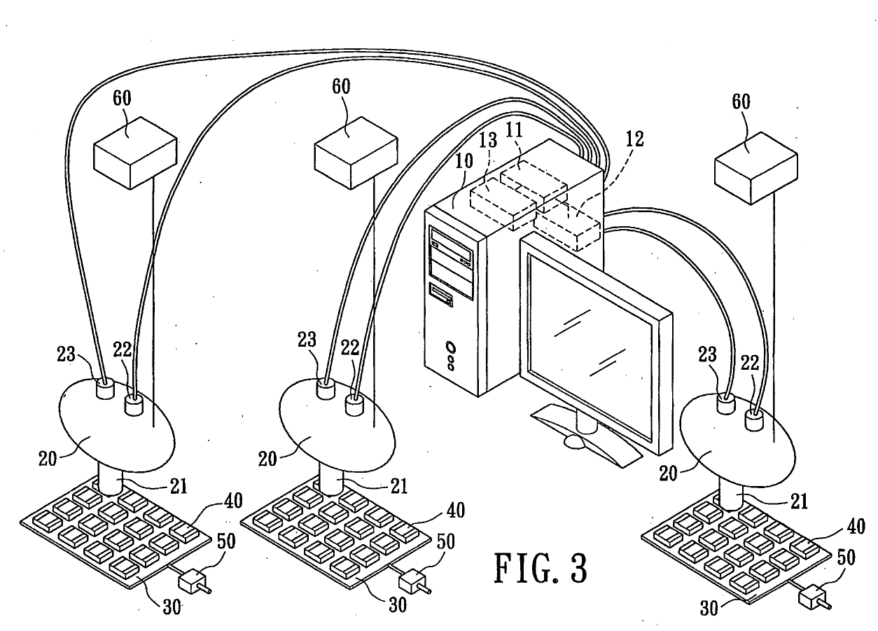

In respect with FIGS. 2 and 3, the mass-production LED test device according to the present invention includes a control module 10 (that includes a complete-optical region photoelectric test machine, YTSD02), at least one integrating sphere module 20 electrically connected to the control module 10, at least one test board 30 corresponding to at the least one integrating sphere module 20, and a motor unit 60 electrically connected to the control module 10 and the integrating sphere module 20. The control module 10 has a central processing unit 11 with a programmable logic controller, and a signal interface unit 12 electrically connected to the central processing unit 11. The integrating sphere module 20 electrically connects the signal interface unit 12 of the control module 10, and has an electrical output entrance 22, an optical output entrance 23 and an optical input entrance 21. The test board 30 has a plurality of pads (not shown) to which a plurality of LEDs 40 are electrically connected, respectively, for supplying required current of each LED 40. The optical input entrance 21 of the integrating sphere module 20 defines a predetermined measure for containing a predetermine amount of the LEDs 40 at one time, and the predetermined amount of the LEDs 40 can be checked their optical characteristics without moving the integrating sphere module 20 or the test board 30. The integrating sphere module 20 has a plurality of probes (not shown) corresponding to the predetermine amount of the LEDs 40, thereby to test the electrical characteristics of each LED 40 by a manner of one by one. These electrical characteristics include a forward bias voltage (VF), a reverse collapse voltage (VZ), a reverse current (IR), and a data forward voltage (DVF). Although the electrical characteristics of the LEDs 40 are still checked one by one, the time to move the integrating sphere module 20 or the test board 30 to align between each single LED 40 and the electrical output entrance 22 of the integrating sphere module 20 is decreased.

The signal interface 12 unit includes a RS 485 signal interface, and the integrating sphere module 20 is electrically connected to the control module 10 via the RS 485 signal interface. The test board 30 is electrically connected to at least one steady current source (which quantity is same as that of the LEDs 40, and shown in FIG. 2) for providing fixed current to each LED 40.

The control module 10, which electrically connects the test board 30, further includes a software module 13 for controlling each LED 40 on the test board 30 in on-state via the software module 13 in turn to check optical characteristics of each LED 40, such as luminous intensity, peak length, wave wide, chromaticity coordinates (CIE), dominated length, purity, color temperature and so on. The predetermined amount of the LEDs 40 contained under the integrating sphere module 20 are controlled in on-state one by one, when the LEDs 40 are tested with their optical characteristics. The software module 13 includes a plurality of automatic execution and classification conditions to divide the LEDs 40 into various specifications. The control module 10 further has at least one manual operation unit (not shown) for setting some execution and classification conditions in a manual manner.

The motor unit 60 is used to drive the integrating sphere module 20 for horizontal and vertical moves to orientate over the predetermined amount of the LEDs 40. The motor unit 60 includes a serve motor or a stepper motor.

The advantages of the mass-production LED test device according to the present invention:
1. The predetermined amount of the LEDs connected in a serial manner can be contained via the optical input entrance is implemented, and the probes of the integrating sphere module 20 are arranged to correspond to the predetermined amount of LEDs for testing electrical characteristics by one by one.
2. The predetermined amount of the LEDs connected in a serial manner can be contained via the optical input entrance is implemented, and the integrating sphere module or the test board should not moves. The predetermined LEDs are drove one by one via current source and the test board for testing optical characteristics.
3. A plurality of the integrating sphere modules and the test boards can be arranged to correspond to each other for meeting the mass-production requirement.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are embraced within the scope of the invention as defined in the appended claims.

What is claimed is:

1. A mass-production LED test device comprising:
a control module including a central processing unit with a programmable logic controller, and a signal interface unit electrically connected to the central processing unit;
at least one integrating sphere module electrically connected to the signal interface unit of the control module, and the integrating sphere module having an electrical output entrance, an optical output entrance and an optical input entrance; and
at least one test board corresponding to the integrating sphere module, and the test board having a plurality of pads to which a plurality of LEDs are electrically connected, respectively, for supplying required input and output of current of each LED;
wherein the optical input entrance of the integrating sphere module defines a predetermined measure for containing a predetermine amount of the LEDs at one time;
wherein the integrating sphere module has a plurality of probes corresponding to the predetermine amount of the LEDs, thereby to test the electrical character of each LED by a manner of one by one.

2. The mass-production LED test device as claimed in claim 1, wherein the signal interface unit includes a RS 485 signal interface, and the integrating sphere module is electrically connected to the control module via the RS 485 signal interface.

3. The mass-production LED test device as claimed in claim 1, wherein the test board is electrically connected to at least one steady current source for providing fixed current to each LED.

4. The mass-production LED test device as claimed in claim 1, wherein the test board is electrically connected to a predetermine amount of steady current sources for providing fixed current to the corresponding predetermine amount of the LEDs.

5. The mass-production LED test device as claimed in claim 1, wherein the control module, which electrically connects the test board, further includes a software module for controlling each LED on the test board in on-state via the software module in turn.

6. The mass-production LED test device as claimed in claim 5, wherein the predetermined amount of the LEDs contained under the integrating sphere module are controlled in on-state one by one, when the LEDs are tested with their optical character.

7. The mass-production LED test device as claimed in claim 5, wherein the software module includes a plurality of automatic execution and classification conditions.

8. The mass-production LED test device as claimed in claim 1, wherein the control module further has at least one manual operation unit for setting some execution and classification conditions in a manual manner.

9. The mass-production LED test device as claimed in claim 1, wherein the control module includes a complete-optical region photoelectric test machine, YTSD02.

10. The mass-production LED test device as claimed in claim 1, further includes a motor unit electrically connected to the control module and the integrating sphere module, so as to drive the integrating sphere module for horizontal and vertical moves.

11. The mass-production LED test device as claimed in claim 10, wherein the motor unit includes a serve motor or a stepper motor.
